(19) United States
(12) Patent Application Publication
(10) Pub. No.: US 2025/0264561 A1
(43) Pub. Date: Aug. 21, 2025

(54) MAGNETIC RESONANCE IMAGING APPARATUS AND MAGNETIC RESONANCE IMAGING METHOD

(71) Applicant: CANON MEDICAL SYSTEMS CORPORATION, Tochigi (JP)

(72) Inventors: Sadanori TOMIHA, Nasushiobara (JP); Tomoki MIYASAKA, Nasushiobara (JP)

(73) Assignee: CANON MEDICAL SYSTEMS CORPORATION, Tochigi (JP)

(21) Appl. No.: 19/058,430

(22) Filed: Feb. 20, 2025

(30) Foreign Application Priority Data
Feb. 21, 2024 (JP) 2024-024902

(51) Int. Cl. G01R 33/56; G01R 33/385

(52) U.S. Cl. CPC G01R 33/56; G01R 33/385

(57) ABSTRACT

A magnetic resonance imaging apparatus includes processing circuitry configured to collect a plurality of magnetic resonance signals while changing relative relationship between echoes and acquisition windows, and generate a magnetic resonance image based on data obtained by combining the plurality of magnetic resonance signals.

### CROSS-REFERENCE TO RELATED APPLICATIONS

This application is based upon and claims the benefit of priority from Japanese Patent Application No. 2024-024902, filed Feb. 21, 2024, the entire contents of which are incorporated herein by reference.

### FIELD

Embodiments described herein relate generally to a magnetic resonance imaging apparatus and a magnetic resonance imaging method.

### BACKGROUND

In a magnetic resonance imaging apparatus, a reception band (band width) is mainly determined by a radio frequency (RF) coil and a sampling rate (SR). Widening of the reception band provides advantages such as reduction in data collection time, reduction in echo time (TE), and suppression of influence by chemical shift, motion artifact, and the like. Widening of the reception band further provides advantages such as widening of a field of view (FOV) when the RF coil is assumed to have a sufficient reception band.

Therefore, when a sampling interval is reduced and an effective sampling rate is increased, the reception band can be widened.

### BRIEF DESCRIPTION OF THE DRAWINGS

FIG. 1 is a diagram illustrating a configuration example of a magnetic resonance imaging apparatus according to an exemplary embodiment;

FIG. 2 is a diagram illustrating an outline of processing performed by the magnetic resonance imaging apparatus according to the exemplary embodiment;

FIG. 3A is a diagram illustrating a phantom used for verification of the processing performed by the magnetic resonance imaging apparatus according to the exemplary embodiment;

FIG. 3B is a diagram illustrating an example of an image obtained by a first pulse sequence in the magnetic resonance imaging apparatus according to the exemplary embodiment;

FIG. 3C is a diagram illustrating an example of an image obtained by a second pulse sequence in the magnetic resonance imaging apparatus according to the exemplary embodiment;

FIG. 3D is a diagram illustrating an example of a combined image obtained in the magnetic resonance imaging apparatus according to the exemplary embodiment;

FIG. 4 is a flowchart illustrating an example of a flow of processing performed by a magnetic resonance imaging apparatus according to a first exemplary embodiment;

FIG. 5 is a diagram illustrating an example of a pulse sequence performed by the magnetic resonance imaging apparatus according to the first exemplary embodiment;

FIG. 6 is a diagram illustrating an example of a pulse sequence performed by the magnetic resonance imaging apparatus according to the first exemplary embodiment;

FIG. 7 is a flowchart illustrating an example of a flow of processing performed by a magnetic resonance imaging apparatus according to a second exemplary embodiment;

FIG. 8 is a diagram illustrating an example of a pulse sequence performed by the magnetic resonance imaging apparatus according to the second exemplary embodiment;

FIG. 9 is a diagram illustrating an example of a pulse sequence performed by a magnetic resonance imaging apparatus according to a third exemplary embodiment;

FIG. 10 is a diagram illustrating an example of a pulse sequence performed by the magnetic resonance imaging apparatus according to the third exemplary embodiment;

FIG. 11 is a diagram illustrating an example of a pulse sequence performed by the magnetic resonance imaging apparatus according to the third exemplary embodiment; and

FIG. 12 is a diagram illustrating an example of a pulse sequence performed by a magnetic resonance imaging apparatus according to a fourth exemplary embodiment.

### DETAILED DESCRIPTION

A magnetic resonance imaging apparatus according to an exemplary embodiment includes processing circuitry configured to collect a plurality of magnetic resonance signals while changing relative relationship between echoes and acquisition windows, and generate a magnetic resonance image based on data obtained by combining the plurality of magnetic resonance signals.

Various Embodiments will be described hereinafter with reference to the accompanying drawings.

Exemplary embodiments of a magnetic resonance imaging apparatus and a magnetic resonance imaging method are described in detail below with reference to the drawings.

### First Exemplary Embodiment

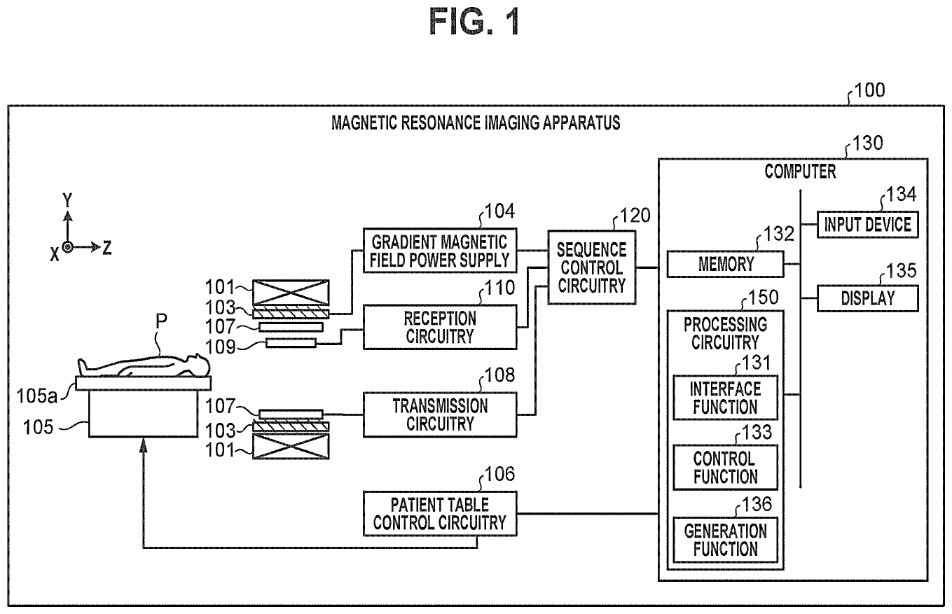

FIG. 1 is a block diagram illustrating a magnetic resonance imaging apparatus 100 according to a first exemplary embodiment. As illustrated in FIG. 1, the magnetic resonance imaging apparatus 100 includes a static magnetic field magnet 101, a static magnetic field power supply (not illustrated), a gradient magnetic field coil 103, a gradient magnetic field power supply 104, a patient table 105, patient table control circuitry 106, a transmission coil 107, transmission circuitry 108, a reception coil 109, reception circuitry 110, sequence control circuitry 120 (sequence control unit), and a computer 130 (also referred to as an “image processing apparatus”). A subject P (e.g., human body) is not included in the magnetic resonance imaging apparatus 100. The configuration illustrated in FIG. 1 is merely an example. For example, the sequence control circuitry 120 and components in the computer 130 may be appropriately integrated or separated.

The static magnetic field magnet 101 is a magnet formed into a substantially cylindrical shape that is hollow inside, and generates a static magnetic field in an internal space. The static magnetic field magnet 101 is, for example, a superconducting magnet. Another example of the static magnetic field magnet 101 may be a permanent magnet.

The gradient magnetic field coil 103 is a coil formed into a substantially cylindrical shape that is hollow inside, and is disposed on an inner side of the static magnetic field magnet 101. The gradient magnetic field coil 103 is formed by combining three coils corresponding to X, Y, and Z axes, which are orthogonal to one another. The three coils generate gradient magnetic fields that vary in magnetic field intensity along the X, Y, and Z axes, by individually receiving supply of a current from the gradient magnetic field power supply 104. The gradient magnetic fields in the X, Y, and Z axes generated by the gradient magnetic field coil 103 are, for example, a slice gradient magnetic field Gs, a phase encoding gradient magnetic field Ge, and a readout gradient magnetic field Gr. The gradient magnetic field power supply 104 supplies the current to the gradient magnetic field coil 103.

The patient table 105 includes a top board 105a on which the subject P is placed, and the top board 105a is inserted into a cavity (imaging port) of the gradient magnetic field coil 103 in a state where the subject P is placed under the control of the patient table control circuitry 106. The patient table 105 is normally installed such that a longitudinal direction is parallel to a center axis of the static magnetic field magnet 101. The patient table control circuitry 106 drives the patient table 105 and moves the top board 105a in the longitudinal direction and a vertical direction under the control of the computer 130.

The transmission coil 107 is disposed on an inner side of the gradient magnetic field coil 103, and generates a high-frequency magnetic field by receiving supply of a radio frequency (RF) pulse from the transmission circuitry 108.

The transmission circuitry 108 includes a pulse generator, an RF generator, a modulator, and an RF amplifier, and supplies the RF pulse corresponding to a Larmor frequency defined by a type of an atom to be a target and magnetic field intensity, to the transmission coil 107. The pulse generator generates a waveform of an RF pulse signal. The RF generator generates an RF signal of a resonance frequency. The modulator modulates an amplitude of the RF signal generated by the RF generator with the waveform generated by the pulse generator, thereby generating the RF pulse signal. The RF amplifier amplifies the RF pulse signal generated by the modulator and outputs the amplified RF pulse signal to the transmission coil 107.

The reception coil 109 is disposed on an inner side of the gradient magnetic field coil 103, and receives magnetic resonance signals (hereinafter, referred to as “MR signals” as necessary) emitted from the subject P due to influence of the high-frequency magnetic field. When receiving the magnetic resonance signals, the reception coil 109 outputs the received magnetic resonance signals to the reception circuitry 110.

The transmission coil 107 and the reception coil 109 described above are merely examples. The transmission coil 107 and the reception coil 109 may each be composed of a single coil or a combination of a plurality of coils among a coil having a transmission function, a coil having a reception function, and a coil having a transmission and reception function.

The reception circuitry 110 detects the magnetic resonance signals output from the reception coil 109, and generates magnetic resonance data based on the detected magnetic resonance signals. More specifically, the reception circuitry 110 performs digital conversion on the magnetic resonance signals output from the reception coil 109 to generate the magnetic resonance data. The reception circuitry 110 transmits the generated magnetic resonance data to the sequence control circuitry 120. The reception circuitry 110 may be provided to a rack apparatus, which includes the static magnetic field magnet 101 and the gradient magnetic field coil 103. Further, some functions of the reception circuitry 110, for example, a digital conversion function of the magnetic resonance signals, may be provided to the reception coil 109.

The sequence control circuitry 120 drives the gradient magnetic field power supply 104, the transmission circuitry 108, and the reception circuitry 110 based on sequence information transmitted from the computer 130, thereby imaging the subject P. The sequence information is information defining a procedure for performing imaging. The sequence information defines intensity and a supply timing of the current supplied from the gradient magnetic field power supply 104 to the gradient magnetic field coil 103, intensity and an application timing of the RF pulse supplied from the transmission circuitry 108 to the transmission coil 107, a detection timing of the magnetic resonance signals by the reception circuitry 110, and the like. For example, the sequence control circuitry 120 is integrated circuitry such as an application specific integrated circuit (ASIC) and a field programmable gate array (FPGA), or electronic circuitry such as a central processing unit (CPU) and a micro processing unit (MPU). Details of a pulse sequence performed by the sequence control circuitry 120 are described below.

The sequence control circuitry 120 drives the gradient magnetic field power supply 104, the RF amplifier through the transmission circuitry 108, and the reception circuitry 110, thereby imaging the subject P. As a result, when receiving the magnetic resonance data from the reception circuitry 110, the sequence control circuitry 120 transfers the received magnetic resonance data to the computer 130. For example, the sequence control circuitry 120 two-dimensionally or three-dimensionally arranges the magnetic resonance data received from the reception circuitry 110, based on positional information imparted by the readout gradient magnetic field, the phase encoding gradient magnetic field, and the slice gradient magnetic field, thereby storing the magnetic resonance data as data configuring a k-space in a memory 132 as a storage unit.

The computer 130 performs control of the entire magnetic resonance imaging apparatus 100, generation of an image, and the like. The computer 130 includes the memory 132, an input device 134, a display 135, and processing circuitry 150. The processing circuitry 150 includes an interface function 131, a control function 133, and a generation function 136.

In the first exemplary embodiment, processing functions performed by the interface function 131, the control function 133, and the generation function 136 are each stored in a form of program executable by a computer, in the memory 132. The processing circuitry 150 is a processor that implements functions corresponding to respective programs by reading the programs from the memory 132 and executing the programs. In other words, the processing circuitry 150 in a state of having read the programs has the functions illustrated in the processing circuitry 150 in FIG. 1. In FIG. 1, description is given by assuming that the single processing circuitry 150 implements the processing functions performed by the interface function 131, the control function 133, and the generation function 136; however, a plurality of independent processors may be combined to constitute the processing circuitry 150, and the processors may execute the programs to implement the functions. In other words, each of the above-described functions may be configured as a program, and one piece of processing circuitry 150 may execute each program. In another example, a specific function may be implemented in dedicated independent program execution circuitry. In FIG. 1, the interface function 131, the control function 133, and the generation function 136 are respectively examples of a reception unit, a control unit, and a generation unit. The sequence control circuitry 120 is an example of a sequence control unit.

The term “processor” used in the above description refers to circuitry such as a central processing unit (CPU), a graphical processing unit (GPU), an application specific integrated circuit (ASIC), and a programmable logic device (e.g., simple programmable logic device (SPLD), complex programmable logic device (CPLD), and field programmable gate array (FPGA)). The processor implements the functions by reading the programs stored in the memory 132 and executing the programs.

In place of storing the programs in the memory 132, the programs may be directly incorporated in circuitry of the processor. In this case, the processor implements the functions by reading the programs incorporated in the circuitry and executing the programs. Each of the patient table control circuitry 106, the transmission circuitry 108, the reception circuitry 110, and the like is also realized by electronic circuitry such as the above-described processor.

The processing circuitry 150 transmits the sequence information to the sequence control circuitry 120 and receives the magnetic resonance data from the sequence control circuitry 120 by using the interface function 131. When receiving the magnetic resonance data, the processing circuitry 150 including the interface function 131 stores the received magnetic resonance data in the memory 132.

The magnetic resonance data stored in the memory 132 is arranged in the k-space by the control function 133. As a result, the memory 132 stores k-space data.

The memory 132 stores the magnetic resonance data received by the processing circuitry 150 including the interface function 131, the k-space data arranged in the k-space by the processing circuitry 150 including the control function 133, image data generated by the processing circuitry 150 including the generation function 136, and the like. For example, the memory 132 is a semiconductor memory element such as a random access memory (RAM) and a flash memory, a hard disk, or an optical disk.

The input device 134 receives various kinds of instructions and information input from an operator. The input device 134 is, for example, a pointing device such as a mouse and a track ball, a selection device such as a mode selection switch, or an input device such as a keyboard. The display 135 displays a graphical user interface (GUI) for receiving input of an imaging condition, an image generated by the processing circuitry 150 including the generation function 136, and the like under the control of the processing circuitry 150 including the control function 133. The display 135 is a display device such as a liquid crystal display.

The processing circuitry 150 controls the entire magnetic resonance imaging apparatus 100 and controls imaging, generation of an image, display of an image, and the like by using the control function 133. For example, the processing circuitry 150 including the control function 133 receives input of the imaging condition (e.g., imaging parameters) on the GUI, and generates the sequence information based on the received imaging condition. The processing circuitry 150 including the control function 133 transmits the generated sequence information to the sequence control circuitry 120. The processing circuitry 150 reads the k-space data from the memory 132 and performs reconstruction processing such as Fourier transform on the read k-space data to generate an image, by using the generation function 136.

The configuration has been described in which, as illustrated in FIG. 1, the magnetic resonance imaging apparatus 100 according to the exemplary embodiment includes two magnets between which the subject is sandwiched or the cylindrical magnet; however, the magnetic resonance imaging apparatus 100 according to the exemplary embodiment is not limited to such a configuration. It is assumed that the magnetic resonance imaging apparatus 100 performs imaging in a region where a static magnetic field is uniform; however, the magnetic resonance imaging apparatus 100 may be used for a technique in which a region having distribution of the static magnetic field is used as an imaging region. A configuration having distribution of the static magnetic field may be, for example, a configuration including only one of the two magnets between which the subject is sandwiched. In a case where the configuration includes the cylindrical magnet, a region where the distribution of the static magnetic field is nonuniform near an opening of a bore may be used as the imaging region.

A background according to the exemplary embodiment is briefly described.

In the magnetic resonance imaging apparatus, a reception band (band width) is mainly determined by a RF coil and a sampling rate (SR). Widening of the reception band provides advantages such as reduction in data collection time, reduction in echo time (TE), and suppression of influence by chemical shift, motion artifact, and the like. Widening of the reception band further provides advantages such as widening of a field of view (FOV) when the RF coil is assumed to have a sufficient reception band. When a sampling interval is reduced and an effective sampling rate is increased, the reception band can be widened.

In consideration of such a background, the magnetic resonance imaging apparatus according to the exemplary embodiment includes the sequence control unit and the generation unit. The sequence control unit collects a plurality of magnetic resonance signals while changing relative relationship between an echo and an acquisition window. The generation unit generates a magnetic resonance image based on data obtained by combining the plurality of magnetic resonance signals.

A magnetic resonance imaging method according to the exemplary embodiment includes collecting a plurality of magnetic resonance signals while changing relative relationship between an echo and an acquisition window, and generating a magnetic resonance image based on data obtained by combining the plurality of magnetic resonance signals.

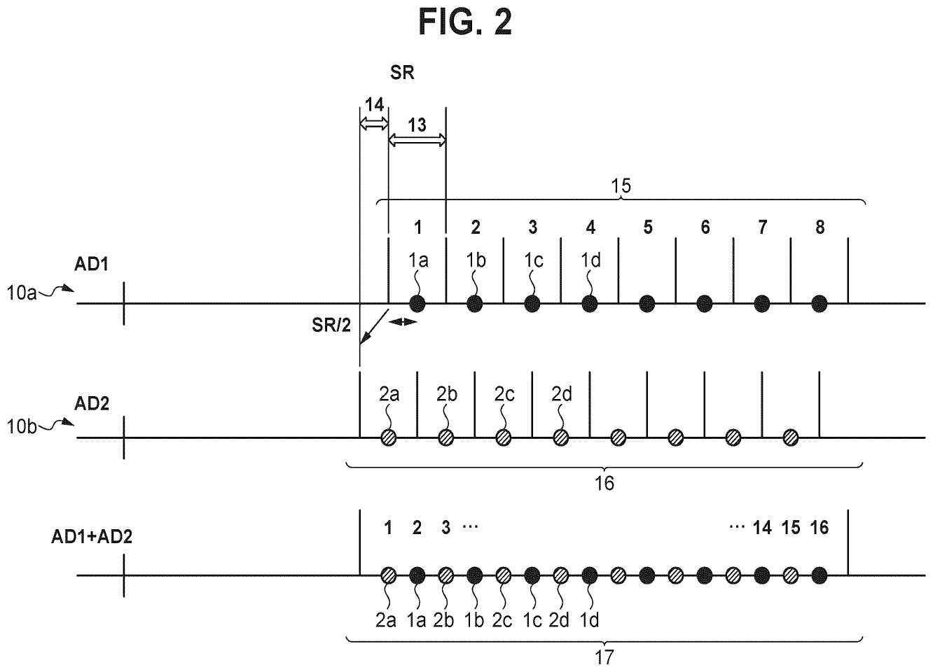

FIG. 2 illustrates an outline of such an idea. The sequence control circuitry 120 performs a pulse sequence a plurality of times. In FIG. 2, the sequence control circuitry 120 performs a first pulse sequence 10a corresponding to first collection AD1, and a second pulse sequence 10b corresponding to second collection AD2. A collection period 15 and a collection period 16 are data collection periods corresponding to the first pulse sequence 10a and the second pulse sequence 10b, respectively. Sampling points 1a, 1b, 1c, and 1d each indicate a data point collected during the collection period 15 of the first pulse sequence 10a. Sampling points 2a, 2b, 2c, and 2d each indicate a data point collected during the collection period 16 of the second pulse sequence 10b. Each sampling point corresponds to, for example, data of one point in the k-space. A sampling interval SR 13 indicates a time interval of sampling. The sampling rate is increased as the sampling interval SR 13 is reduced.

In the pulse sequence performed the plurality of times, the sequence control circuitry 120 performs collection while relatively shifting an echo and an acquisition window AW. For example, the sequence control circuitry 120 performs collection while shifting a timing of the acquisition window AW by an interval 14 that is ½ of the sampling interval SR 13 between the first pulse sequence 10a and the second pulse sequence 10b. Subsequently, after data collection, as illustrated in a lower part in FIG. 2, the sequence control circuitry 120 combines data obtained by the first pulse sequence 10a and data obtained by the second pulse sequence 10b in the k-space to generate combined data 17, and performs image reconstruction based on the combined data 17.

As described above, the sequence control circuitry 120 can improve the sampling rate in a pseudo manner by shifting the echo by a time interval smaller than the sampling interval SR. For example, the sequence control circuitry 120 can widen a collection band width to N times by shifting the timing of the acquisition window AW by 1/N of the sampling interval SR.

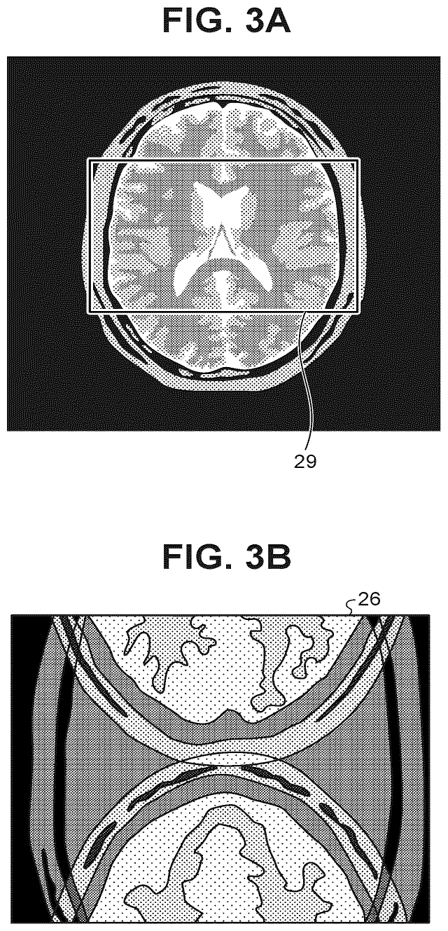

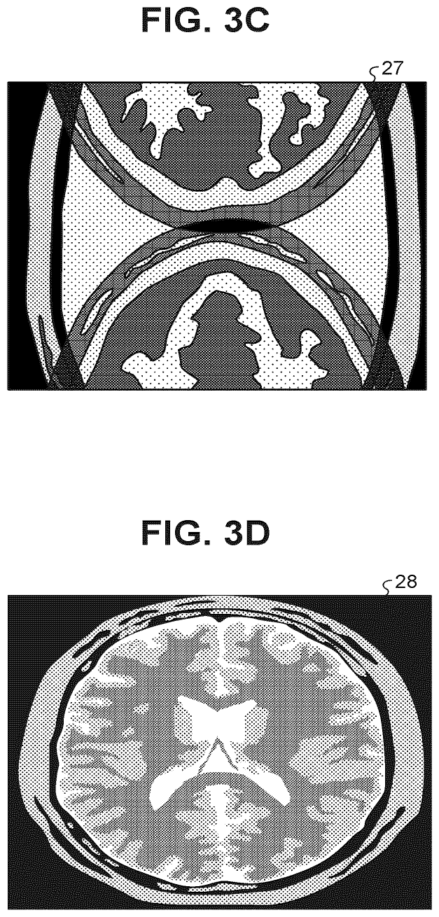

FIGS. 3A to 3D illustrate examples of an image obtained by the method according to the exemplary embodiment. FIG. 3A illustrates a phantom subjected to imaging, and a region 29 is a field of view (FOV). The sequence control circuitry 120 has acquired data twice by shifting the timings of the echo and the acquisition window AW. An image 26 illustrated in FIG. 3B is an image obtained by reconstructing the data obtained by the first pulse sequence 10a. An image 27 illustrated in FIG. 3C is an image obtained by reconstructing the data obtained by the second pulse sequence 10b. An image 28 illustrated in FIG. 3D is an image obtained by combining the data obtained by the first pulse sequence 10a and the data obtained by the second pulse sequence 10b and then reconstructing the combined data. As illustrated, when collection is performed a plurality of times while shifting the timings of the echo and the acquisition window AW, the sampling rate can be effectively increased. Further, the sampling interval can be effectively shortened by half. Thus, the band width is increased, and imaging can be performed on the wider FOV.

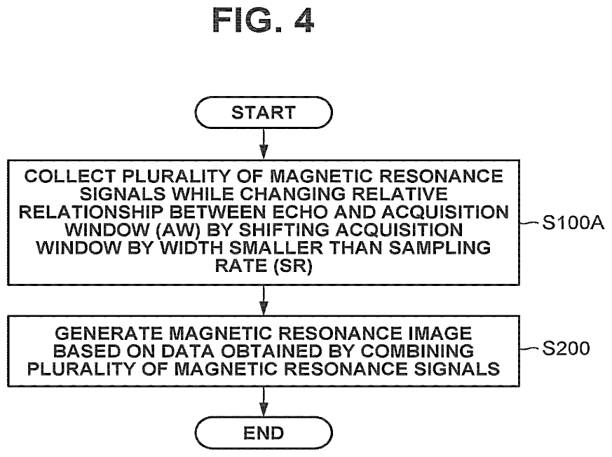

The exemplary embodiment is described in more detail with reference to FIGS. 4 to 6. FIG. 4 is a flowchart illustrating a flow of processing performed by the magnetic resonance imaging apparatus 100 according to the first exemplary embodiment.

First, in step S100A, the sequence control circuitry 120 collects the plurality of magnetic resonance signals while changing relative relationship between the echo and the acquisition window. The sequence control circuitry 120 collects the plurality of magnetic resonance signals while changing the relative relationship between the echo and the acquisition window AW by shifting the acquisition window AW by a width smaller than the sampling interval SR.

FIG. 5 illustrates an example in a case where the pulse sequence performed by the sequence control circuitry 120 is a pulse sequence of a spin echo (SE). The first pulse sequence 10a performed by the sequence control circuitry 120 in step S100A includes a 90-degree pulse 20, a 180-degree pulse 21, and an acquisition window AW 23a. After a TE 22 is elapsed from application of the 90-degree pulse 20, an echo 25 is generated. The second pulse sequence 10b performed by the sequence control circuitry 120 includes the 90-degree pulse 20, the 180-degree pulse 21, and an acquisition window AW 23b. After the TE 22 is elapsed from application of the 90-degree pulse 20, the echo 25 is generated. At this time, the sequence control circuitry 120 shifts the acquisition window AW 23b from the acquisition window AW 23a by a period 24 equivalent to ½ of the sampling interval SR. In this manner, the sequence control circuitry 120 collects the plurality of magnetic resonance signals while changing the relative relationship between the echo and the acquisition window. In this embodiment, the 90-degree pulse is described as an example of an excitation pulse, but a pulse with a flip angle other than 90 degrees can also be used. In this embodiment, the 180-degree pulse is described as an example of a refocusing pulse, but pulses with flip angles other than 180 degrees can also be used.

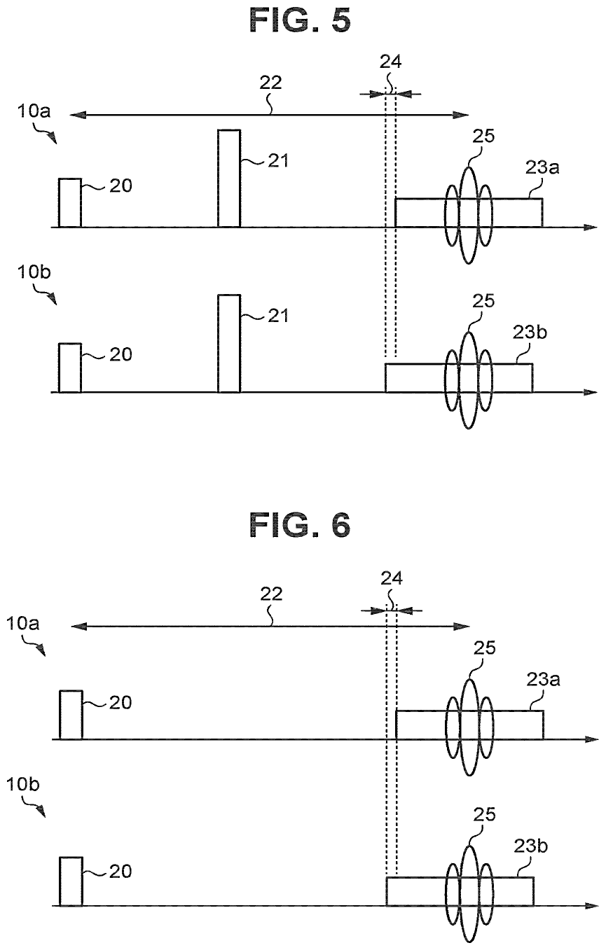

FIG. 6 illustrates an example in a case where the pulse sequence performed by the sequence control circuitry 120 is a pulse sequence of a field echo (FE). The first pulse sequence 10a performed by the sequence control circuitry 120 in step S100A includes the 90-degree pulse 20 and the acquisition window AW 23a. After the TE 22 is elapsed from application of the 90-degree pulse 20, the echo 25 is generated. The second pulse sequence 10b performed by the sequence control circuitry 120 includes the 90-degree pulse 20 and the acquisition window AW 23b. After the TE 22 is elapsed from application of the 90-degree pulse 20, the echo 25 is generated. At this time, the sequence control circuitry 120 shifts the acquisition window AW 23b from the acquisition window AW 23a by the period 24 equivalent to ½ of the sampling interval SR. In this manner, the sequence control circuitry 120 collects the plurality of magnetic resonance signals while changing the relative relationship between the echo and the acquisition window.

Description is again provided with reference to FIG. 4. In step S200, the processing circuitry 150 generates, by using the generation function 136, a magnetic resonance image based on the data obtained by combining the plurality of magnetic resonance signals.

In the examples illustrated in FIG. 5 and FIG. 6, the sequence control circuitry 120 collects the plurality of magnetic resonance signals twice while changing the relative relationship between the echo and the acquisition window; however, the exemplary embodiment is not limited thereto. The sequence control circuitry 120 may collect the plurality of magnetic resonance signals while shifting an acquisition window AW by 1/N of the sampling interval, where N is a natural number. Thus, the sequence control circuitry 120 can collect the plurality of magnetic resonance signals while widening the collection band width of the magnetic resonance signals to N times as compared with a case where collection of the plurality of magnetic resonance signals is performed once.

As described above, in the first exemplary embodiment, the sequence control circuitry 120 collects the plurality of magnetic resonance signals while changing the relative relationship between the echo and the acquisition window AW by shifting the acquisition window AW. As a result, the sampling rate can be effectively increased. Further, the sampling interval can be effectively shortened. Thus, the band width is increased, and imaging can be performed on the wider FOV.

### Second Exemplary Embodiment

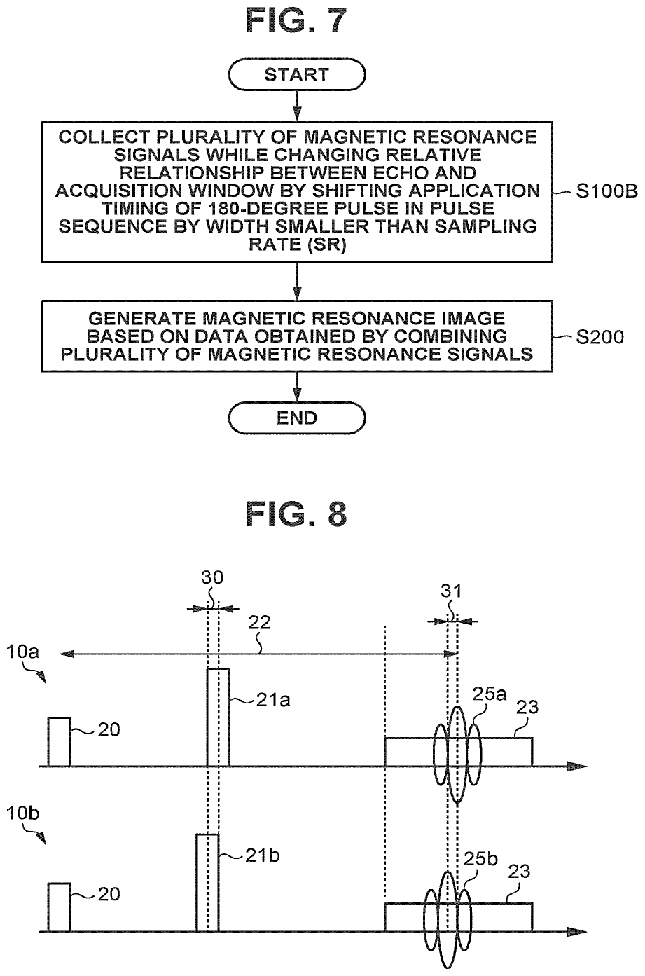

In the first exemplary embodiment, the case is described where the sequence control circuitry 120 collects the plurality of magnetic resonance signals while changing the relative relationship between the echo and the acquisition window by shifting the acquisition window by the width smaller than the sampling interval. In a second exemplary embodiment, a case is described where, in the pulse sequence of the spin echo, the relative relationship between the echo and the acquisition window is changed by shifting an application timing of a 180-degree pulse by a width smaller than the sampling interval. FIG. 7 is a flowchart illustrating a flow of processing performed by the magnetic resonance imaging apparatus 100 according to the second exemplary embodiment.

First, in step S100B, the sequence control circuitry 120 collects the plurality of magnetic resonance signals while changing the relative relationship between the echo and the acquisition window. In the second exemplary embodiment, the sequence control circuitry 120 performs the pulse sequence for generating the spin echo, and collects the plurality of magnetic resonance signals while changing the relative relationship between the echo and the acquisition window AW by shifting the application timing of the 180-degree pulse in the pulse sequence by a width smaller than the sampling interval.

FIG. 8 illustrates such an example. The first pulse sequence 10a performed by the sequence control circuitry 120 in step S100B includes the 90-degree pulse 20, a 180-degree pulse 21a, and an acquisition window AW 23. After the TE 22 is elapsed from application of the 90-degree pulse 20, an echo 25a is generated. The second pulse sequence 10b performed by the sequence control circuitry 120 includes the 90-degree pulse 20, a 180-degree pulse 21b, and the acquisition window AW 23. After the TE 22 is elapsed from application of the 90-degree pulse 20, an echo 25b is generated. At this time, the sequence control circuitry 120 shifts the application timing of the 180-degree pulse 21b from the application timing of the 180-degree pulse 21a by a period 30 equivalent to ½ of the sampling interval SR. Along with a shift between the application timing of the 180-degree pulse 21a and the application timing of the 180-degree pulse 21b, a shift 31 occurs between a generation time of the echo 25a and a generation time of the echo 25b. In this manner, the sequence control circuitry 120 collects the plurality of magnetic resonance signals while changing the relative relationship between the echo and the acquisition window.

Description is again provided with reference to FIG. 7. In step S200, the processing circuitry 150 generates, by using the generation function 136, a magnetic resonance image based on the data obtained by combining the plurality of magnetic resonance signals.

In the example illustrated in FIG. 7, the case is described where the sequence control circuitry 120 collects the plurality of magnetic resonance signals twice while changing the relative relationship between the echo and the acquisition window; however, the exemplary embodiment is not limited thereto. The sequence control circuitry 120 may collect the plurality of magnetic resonance signals while shifting the application timing of the 180-degree pulse by 1/N of the sampling interval, where N is a natural number. Thus, the sequence control circuitry 120 can collect the plurality of magnetic resonance signals while widening the collection band width of the magnetic resonance signals to N times as compared with the case where collection of the plurality of magnetic resonance signals is performed once.

As described above, in the second exemplary embodiment, the sequence control circuitry 120 collects the plurality of magnetic resonance signals while changing the relative relationship between the echo and the acquisition window AW by shifting the application timing of the 180-degree pulse by the width smaller than the sampling interval SR. As a result, as in the first exemplary embodiment, the sampling rate can be effectively increased. Further, the sampling interval can be effectively shortened. Thus, the band width is increased, and imaging can be performed on the wider FOV.

In the first exemplary embodiment, the case is described where the sequence control circuitry 120 collects the plurality of magnetic resonance signals while changing the relative relationship between the echo and the acquisition window by shifting the acquisition window by the width smaller than the sampling interval. In the second exemplary embodiment, the case is described where, in the pulse sequence of the spin echo, the relative relationship between the echo and the acquisition window is changed by shifting the application timing of the 180-degree pulse by the width smaller than the sampling interval. The two exemplary embodiments can be combined.

More specifically, the sequence control circuitry 120 may collect the plurality of magnetic resonance signals while changing the relative relationship between the echo and the acquisition window by shifting the acquisition window by the width smaller than the sampling interval and shifting the application timing of the 180-degree pulse in the pulse sequence by the width smaller than the sampling interval. For example, the sequence control circuitry 120 performs collection by shifting the acquisition window AW by ¼ of the sampling interval SR and shifting the application timing of the 180-degree pulse by ¼ of the sampling interval SR. In this manner, both the acquisition window AW and the application timing of the 180-degree pulse are shifted, which makes it possible to effectively shorten the sampling interval while maintaining a small shift amount of each of the acquisition window AW and the application timing of the 180-degree pulse.

### Third Exemplary Embodiment

In the first exemplary embodiment and the second exemplary embodiment, the case is described where the sequence control circuitry 120 performs the pulse sequence of a single echo. In a third exemplary embodiment, however, the pulse sequence is not limited thereto, and the sequence control circuitry 120 may perform a pulse sequence having multiple echoes.

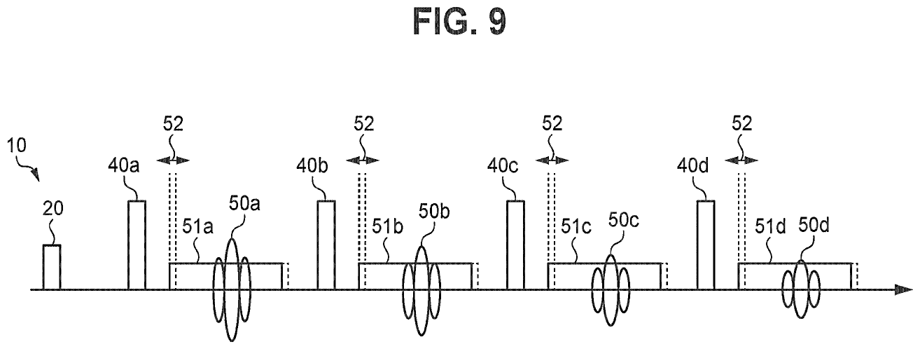

FIG. 9 illustrates an example of a pulse sequence in a case where the plurality of magnetic resonance signals is collected by shifting the acquisition window AW by a width smaller than the sampling interval. A pulse sequence 10 is an exemplary configuration of the pulse sequence at one time among a plurality of times the pulse sequence is performed. The pulse sequence 10 is a pulse sequence having multiple echoes in which a plurality of 180-degree pulses 40a, 40b, 40c, and 40d is applied relative to one 90-degree pulse 20, and therefore, a plurality of echoes 50a, 50b, 50c and 50d is generated. Acquisition windows AW 51a, 51b, 51c, and 51d are acquisition windows corresponding to the respective echoes.

In step S100A, the sequence control circuitry 120 performs a plurality of pulse sequences while simultaneously shifting the acquisition windows AW 51a, 51b, 51c, and 51d by a period 52, which is shorter than the sampling interval SR, in each of the pulse sequences. For example, the sequence control circuitry 120 performs N pulse sequences while simultaneously shifting the acquisition windows AW 51a, 51b, 51c, and 51d by the period 52 equivalent to 1/N of the sampling interval SR in each of the pulse sequences. In this manner, the sequence control circuitry 120 collects the plurality of magnetic resonance signals while changing the relative relationship between the echo and the acquisition window. In step S200, the processing circuitry 150 generates, by using the generation function 136, a magnetic resonance image based on the data obtained by combining the plurality of magnetic resonance signals.

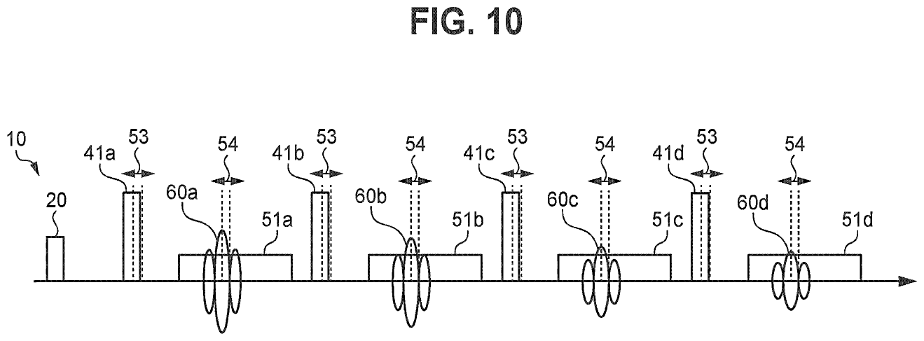

FIG. 10 illustrates an example of a sequence in a case where the plurality of magnetic resonance signals is collected by shifting the application timing of the 180-degree pulse by a width smaller than the sampling interval SR. As in FIG. 9, the pulse sequence 10 is an exemplary configuration of the pulse sequence at one time among a plurality of times the pulse sequence is performed. The pulse sequence 10 is a pulse sequence having multiple echoes in which a plurality of 180-degree pulses 41a, 41b, 41c, and 41d is applied relative to one 90-degree pulse 20, and therefore, a plurality of echoes 60a, 60b, 60c, and 60d is generated. The acquisition windows AW 51a, 51b, 51c, and 51d are acquisition windows corresponding to the respective echoes.

In step S100A, the sequence control circuitry 120 performs a plurality of pulse sequences while simultaneously shifting the application timings of the 180-degree pulses by a period 53, which is shorter than the sampling interval SR, in each of the pulse sequences. For example, the sequence control circuitry 120 performs N pulse sequences while simultaneously shifting the application timings of the 180-degree pulses by the period 53 equivalent to 1/N of the sampling interval SR in each of the pulse sequences. When the application timings of the 180-degree pulses are each shifted by the period 53, timings of generated echoes are each shifted by a period 54. In this manner, the sequence control circuitry 120 collects the plurality of magnetic resonance signals while changing the relative relationship between the echo and the acquisition window AW. In step S200, the processing circuitry 150 generates, by using the generation function 136, a magnetic resonance image based on the data obtained by combining the plurality of magnetic resonance signals.

In the examples illustrated in FIG. 9 and FIG. 10, the case is described where the relative relationship between the echo and the acquisition window AW is not changed in one pulse sequence; however, the exemplary embodiment is not limited thereto. The sequence control circuitry 120 may collect the plurality of magnetic resonance signals while changing the relative relationship between each of echoes constituting multi-echo and the acquisition window AW.

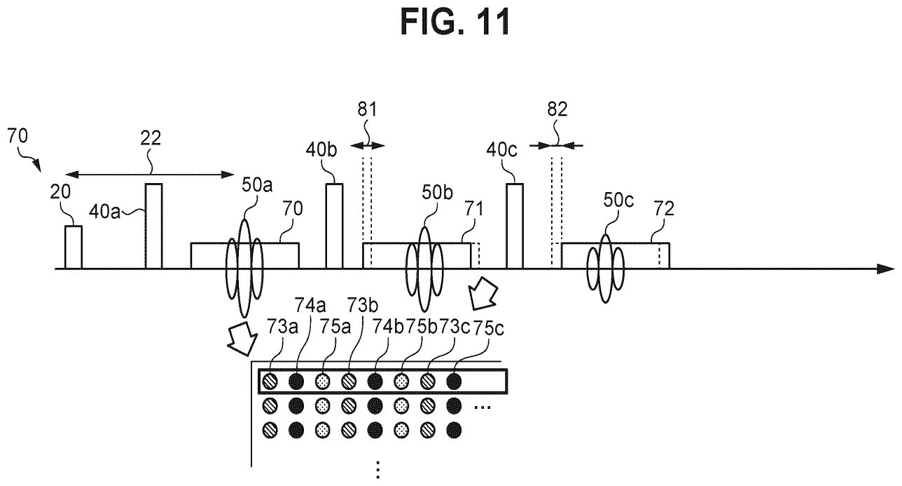

FIG. 11 illustrates such an example. In the example illustrated in FIG. 11, in a pulse sequence 70, the relative relationship between the echo and the acquisition window AW is changed. The pulse sequence 70 is a pulse sequence having multiple echoes in which a plurality of 180-degree pulses 40a, 40b, and 40c is applied relative to one 90-degree pulse 20, and therefore, a plurality of echoes 50a, 50b, and 50c is generated. Acquisition windows AW 70, 71, and 72 are acquisition windows corresponding to the respective echoes.

In step S100A, the sequence control circuitry 120 performs the pulse sequence 70 while shifting the acquisition windows AW 71 and 72 from the acquisition window AW 70 by periods 81 and 82, which are shorter than the sampling interval SR. As a result, positions in the k-space where data collection with the acquisition windows AW 71 and 72 is performed are shifted from a position in the k-space where the data collection is performed with the acquisition window AW 70. For example, when it is assumed that data points of the k-space data collected by the acquisition window AW 70 are data points 74a, 74b, and 74c, data points of the k-space data collected by the acquisition window AW 71 are data points 73a, 73b, and 73c, and data points of the k-space data collected by the acquisition window AW 72 are data points 75a, 75b, and 75c. The processing circuitry 150 can generate, by using the generation function 136, a magnetic resonance image based on the data obtained by combining the magnetic resonance signals.

As described above, in the third exemplary embodiment, the case where the pulse sequence having multiple echoes is performed is described. Therefore, even in the pulse sequence having multiple echoes, the sampling rate can be effectively increased. Further, the sampling interval can be effectively shortened. Thus, the band width is increased, and imaging can be performed on the wider FOV.

### Fourth Exemplary Embodiment

In a fourth exemplary embodiment, a case is described where, in a pulse sequence of a field echo, the sequence control circuitry 120 changes relative positional relationship between the echo and the acquisition window by shifting an application timing of a readout gradient magnetic field by a width smaller than the sampling interval.

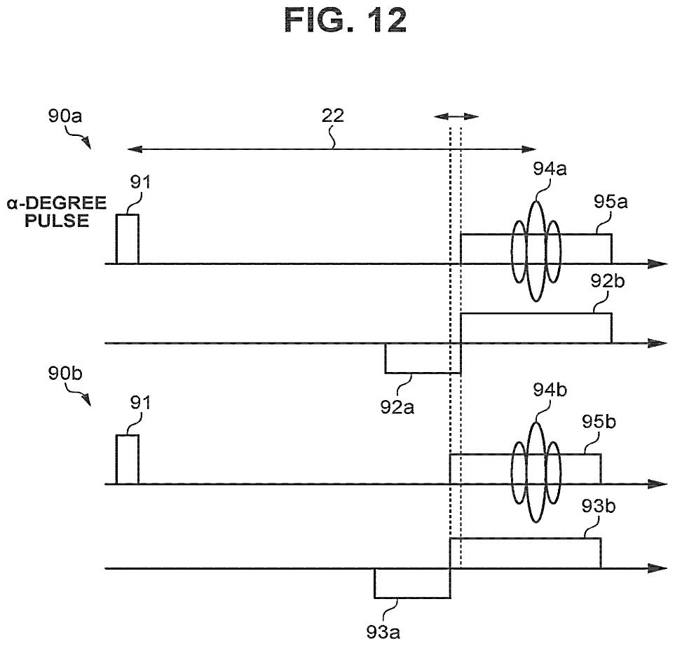

FIG. 12 illustrates an example in a case where the pulse sequence performed by the sequence control circuitry 120 is the pulse sequence of a field echo (FE), and the relative positional relationship between the echo and the acquisition window AW is changed by shifting the application timing of the readout gradient magnetic field. A first pulse sequence 90a performed by the sequence control circuitry 120 in step S100A includes an a-degree pulse 91 and an acquisition window AW 95a. After the TE 22 is elapsed from application of the a-degree pulse 91, an echo 94a is generated by influence of readout gradient magnetic fields 92a and 92b. A second pulse sequence 90b performed by the sequence control circuitry 120 includes the a-degree pulse 91 and an acquisition window AW 95b, and an echo 94b is generated by influence of readout gradient magnetic fields 93a and 93b. At this time, the sequence control circuitry 120 collects the plurality of magnetic resonance signals by changing the relative relationship between the echo and the acquisition window AW by shifting an application timing of the readout gradient magnetic field 93b by a width smaller than the sampling interval. In step S200, the processing circuitry 150 generates, by using the generation function 136, a magnetic resonance image based on the data obtained by combining the plurality of magnetic resonance signals.

In FIG. 12, for simplification, a waveform of the readout gradient magnetic field 93b is illustrated so as to straightly rise; however, an actual waveform of the readout gradient magnetic field 93b includes rounding and overshoot. In other words, in the exemplary embodiment, shifting of the application timing of the readout gradient magnetic field 93b is not limited to a case where a rising timing of the readout gradient magnetic field 93b is changed. A time of the center of the echo 94b is determined by an integrated value of the readout gradient magnetic fields 93a and 93b applied by that time, and the echo 94b is generated when an integrated value of intensity on a negative side of the readout gradient magnetic field 93a and an integrated value of intensity on a positive side of the readout gradient magnetic field 93b are equal to each other. Accordingly, in actuality, the sequence control circuitry 120 controls the time of the echo 94b by controlling not only the rising time of the readout gradient magnetic field 93b but also the entire waveforms of the readout gradient magnetic field 93a and the readout gradient magnetic field 93b.

As described above, in the fourth exemplary embodiment, the case is described where the application timing of the readout gradient magnetic field is controlled. By controlling the application timing of the readout gradient magnetic field, the sampling rate can be effectively increased.

In the fourth exemplary embodiment, the case is described where the sampling rate is effectively increased by controlling the application timing of the readout gradient magnetic field. The fourth exemplary embodiment can be combined with the first exemplary embodiment and the second exemplary embodiment. The sampling rate can be effectively increased by further controlling, for example, the acquisition window and the application timing of the 180-degree pulse.

According to at least one of the exemplary embodiments described above, the data can be collected while the effective sampling rate is increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus, comprising processing circuitry configured to:
collect a plurality of magnetic resonance signals while changing relative relationship between echoes and acquisition windows; and
generate a magnetic resonance image based on data obtained by combining the plurality of magnetic resonance signals.

2. The magnetic resonance imaging apparatus according to claim 1, wherein the processing circuitry is configured to collect the plurality of magnetic resonance signals while changing the relative relationship by shifting the acquisition windows by a width smaller than a sampling interval.

3. The magnetic resonance imaging apparatus according to claim 2, wherein the processing circuitry is configured to perform a pulse sequence of a spin echo or a field echo.

4. The magnetic resonance imaging apparatus according to claim 2, wherein the processing circuitry is configured to collect the plurality of magnetic resonance signals while widening a collection band width of the magnetic resonance signals to N times as compared with a case where collection of the plurality of magnetic resonance signals is performed once, by shifting the acquisition windows by 1/N of the sampling interval, where N is a natural number.

5. The magnetic resonance imaging apparatus according to claim 1, wherein the processing circuitry is configured to perform a pulse sequence for generating a spin echo and to collect the plurality of magnetic resonance signals while changing the relative relationship by shifting an application timing of a refocusing pulse in the pulse sequence by a width smaller than a sampling interval.

6. The magnetic resonance imaging apparatus according to claim 5, wherein the processing circuitry is configured to widen a collection band width of the magnetic resonance signals to N times as compared with a case where collection of the magnetic resonance signals is performed once, by collecting the plurality of magnetic resonance signals while shifting the application timing of the refocusing pulse by 1/N of the sampling interval, where N is a natural number.

7. The magnetic resonance imaging apparatus according to claim 5, wherein the processing circuitry is configured to collect the plurality of magnetic resonance signals while changing the relative relationship by further shifting the acquisition windows by a width smaller than the sampling interval.

8. The magnetic resonance imaging apparatus according to claim 1, wherein the processing circuitry is configured to collect the plurality of magnetic resonance signals while changing the relative relationship by shifting an application timing of a readout gradient magnetic field by a width smaller than a sampling interval.

9. The magnetic resonance imaging apparatus according to claim 1, wherein the processing circuitry is configured to perform a pulse sequence having multiple echoes.

10. The magnetic resonance imaging apparatus according to claim 9, wherein the processing circuitry is configured to collect the plurality of magnetic resonance signals while changing the relative relationship for each echo constituting the multiple echoes

11. A magnetic resonance imaging method, comprising:
collecting a plurality of magnetic resonance signals while changing relative relationship between echoes and acquisition windows; and
generating a magnetic resonance image based on data obtained by combining the plurality of magnetic resonance signals.
